(19) United States
(12) Patent Application Publication
(10) Pub. No.: US 2025/0125152 A1
(43) Pub. Date: Apr. 17, 2025

(54) METHOD AND DEVICE FOR COMPENSATING FOR DISTORTIONS

(71) Applicant: EV Group E. Thallner GmbH, St. Florian am Inn (AT)

(72) Inventors: Thomas Uhrmann, St. Florian am Inn (AT); Markus Wimplinger, St. Florian am Inn (AT); Friedrich Paul Lindner, St. Florian am Inn (AT); Jurgen Burggraf, St. Florian am Inn (AT); Thomas Wagenleitner, St. Florian am Inn (AT); Dominik Zinner, St. Florian am Inn (AT); Martin Finger, St. Florian am Inn (AT); Harald Rohringer, St Florian am Inn (AT)

(73) Assignee: EV Group E. Thallner GmbH, St. Florian am Inn (AT)

(21) Appl. No.: 18/686,473

(22) PCT Filed: Nov. 2, 2021
(86) PCT No.: PCT/EP2021/080376

§ 371 Date: Feb. 26, 2024

(51) Int. Cl. H01L 21/304; H01L 21/67

(52) U.S. Cl. CPC H01L 21/304; H01L 21/67092; H01L 21/67288

(57) ABSTRACT

The invention relates to a method and a device for the compensation of distortions on a substrate surface of a substrate, a method for bonding two substrates and a product.

### FIELD OF THE INVENTION

The invention relates to a method and a device according to the coordinated claims.

### BACKGROUND OF THE INVENTION

In the semiconductor industry, use is made of different substrates to produce components, so-called devices. The most frequently used type of substrates are also called wafers.

The production process of such a component involves a plurality, sometimes hundreds, of processes with a plurality of process steps. The processes are for example coating, embossing, exposure, cleaning, etching, bonding, debonding or back-thinning processes. The purpose of the different processes is usually to produce several hundred up to a thousand individual components on one substrate.

All these processes are basically error-prone. For example, a lithographic mask can be defined with a high degree of accuracy in a computer. Their production, however, is error-prone due to the production process. Defective exposures necessarily also arise from a defective mask. It is also conceivable for a maskless lithographic process to be used, in which one or more spatial light modulators (SLMs), in particular digital micromirror devices (DMDs) are used, with which defective exposure takes place which has to be corrected.

Similar problems occur in processes in which there are strong mechanical effects on a substrate. A substrate can comprise very exact structures on a substrate surface. However, if the rear side of the substrate is ground back or even just polished, this can lead to an undesired distortion of the substrate, in particular of the substrate surface.

It is thus possible for substrates also to become deformed and distorted over a large area. For example, substrates are on the one hand thinned by the grinding and/or polishing processes, on the other hand internal stresses are also built up in the substrates, which lead to a convex, concave curvature or to a global curvature pattern, which changes as a function of the location. Components on such substrates, even when they were in an undistorted state before the grinding and/or polishing processes, are thus subsequently distorted again.

It would also be conceivable for two substrates to be bonded together and for a distortion of one of the outer substrate surfaces to occur due to the bonding process. If one of the outer substrate surfaces is bonded with a further substrate which is undistorted, the bonding surface between the two substrates is nonetheless defective.

In this publication, the difference between an actual state and an intended state is referred to as a distortion. This distortion can either be of a mechanical nature, such as arises for example when mechanical stresses are introduced by a grinding process, or it may be the deviation of a photolithographically exposed layer from its intended state, which arises due to a defective or at least poorly produced photolithographic mask. In this case, therefore, the substrate on which the photolithographically exposed layer is present may itself be undistorted, but the structure produced thereon is produced distorted.

The distortions are generally dependent on the location. In particular, they change continuously as a function of the location. The distortions can therefore also be referred to as distortion fields. Distortions are thus either local and/or global. For the sake of simplicity, however, mention will always only be made of distortions in the subsequent text. Distortions are preferably described as, in particular, two-dimensional vectors. The vectors lie inside a tangential plane at the point of their origin.

Distortions can be present and/or compensated for on the active substrate surface and/or on the passive substrate surface lying opposite the active substrate surface. Active substrate surface is understood in particular to mean the substrate surface on which functional elements, for example MEMS, LEDs, transistors, coatings etc. are present, whereas the passive substrate surface serves for example for the fixing. Each passive substrate surface can become the active substrate surface in a production process. It is also conceivable for a substrate to have two active substrate surfaces.

At the beginning of the process, both substrate surfaces are usually passive. Especially in the case of thin substrates, it is conceivable for compensation of a distortion to take effect over the substrate thickness and therefore also on the opposite substrate side. The compensation of distortions on the active substrate surface is thus possible from the passive substrate surface. Preferably, however, the distortions are compensated for directly at the active substrate surface, in particular because preferably particularly efficient monitoring is thus possible and conceivable.

In the prior art, there are publications from which influencing of a distortion of a substrate emerge. Publication WO2012083978A1 shows for example a substrate holder, which can compensate for local and/or global distortions of a substrate with the aid of a number of distortion elements. Publication WO 2021079786A1 shows a device with the aid of which distortions can be measured and partially compensated for.

The problem in the prior art consists in particular in the fact that the compensation of local and/or global distortions takes place by means of the substrate holder. In particular, the compensation of the distortions is not permanent, i.e. the distortions re-emerge when the active controllable deformation elements of the substrate holders are switched off or the substrates are removed.

The substrate deforms back into its original shape, i.e. it behaves elastically. In the prior art, an attempt is made to compensate for the distortions by means of such substrate holders before further process steps are carried out on the substrate. One of the most important processes, in which it must be ensured that the local and/or global distortions of at least one substrate surface have been compensated for before proceeding onwards, is the aforementioned bonding.

It is the aim of the present invention, therefore, to eliminate the drawbacks of the prior art.

### SUMMARY OF THE INVENTION

The drawbacks of the prior art are solved with the subject-matter of the present invention. Advantageous developments of the invention are indicated in the sub-claims. All combinations of at least two of the features stated in the description, in the claims and/or the figures also fall within the scope of the invention. Values lying within the stated limits are also disclosed as limiting values in the stated value ranges and can be claimed in any combination.

The invention relates to a method for compensating for distortions on at least one substrate surface of a substrate, wherein at least one local action is produced on at least one of the substrate surfaces.

Furthermore, the invention relates to a device for compensating for distortions on at least one substrate surface of a substrate, wherein at least one local action can be produced on at least one of the substrate surfaces.

The invention further relates to a product produced with the method according to the invention and/or the device according to invention.

Especially when a plurality of distortions are present, not all the distortions present have to be compensated for. It is also possible to let several distortions continue to be present, in order to achieve a desired distortion. Preferably, however, distortions in the vicinity of functional units and structures are mainly compensated for, since such distortions represent a drawback in further process steps.

In particular, it is conceivable that the at least one local action is generated with the purpose of producing deformations in order to bring the substrate into a desired shape. In particular, a partial region of the substrate which does not have any distortion can be deformed by the at least one local action, in order to compensate for a distortion in another partial region.

The at least one local action compensates for the at least one distortion in at least one substrate surface and in particular produces deformations at another point. The newly produced deformations will improve the newly created state of the at least one substrate surface.

In particular, provision is made such that the device comprises means for generating the local action, wherein the means for generating the local action preferably comprise a laser.

The substrate is in particular a wafer.

The substrate or the substrates can have any arbitrary shape, but they are preferably round. The diameter of the substrates is in particular industrially standardised. The diameters standard in the industry for wafers are 1 inch, 2 inches, 3 inches, 4 inches, 5 inches, 6 inches, 8 inches, 12 inches and 18 inches.

In principle, however, the invention can be used for any substrate irrespective of its diameter.

Distortion Includes both local and global distortions.

Local distortions are understood in particular to mean locally limited, small-area distortions, which have no influence or only very little influence on the overall surface of the substrate.

A global distortion is understood in particular two mean the large-area deviation of a substrate, in particular a wafer, from its flat shape. Particularly thin substrates have the property to become deformed or bent over a large area by mechanical and/or chemical influence and/or gravitation. In such cases, the substrates exhibit marked global deviations from flatness. Typical, for example, is a convex, sagging shape of a substrate fixed only at the periphery on an upper substrate holder. These gravitational effects are mostly reversible as soon as the substrate is supported over the whole area. Grinding and polishing can curve a substrate permanently and over a large area. These curvatures can be convex or concave or change as a function of the location. Coating and/or etching of a substrate can also lead to a global distortion. In the case of a coating, the global distortion can usually be traced back to the difference in the thermal expansion coefficients between the coating and the substrate. Since coatings are usually carried out at higher temperatures and the coated substrate is cooled after the coating, a global distortion of the substrate takes place due to the build-up of thermal stresses.

Global distortions can be compensated for by the compensation of local distortions. In particular, a global distortion can be compensated for by carrying out a plurality of compensations of local distortions along a grid of the at least one substrate surface. The type and/or magnitude, in particular the intensity, of the compensations in the grid changes as a function of the location, so that the global distortion is compensated for.

The origin of distortions can also be differentiated in terms of whether the distortions are generated by the property of the substrate or by the environment. For example, a coating, a grinding or polishing process, components produced in the substrate, a density of components on the substrate varying as a function of the location etc. can lead to distortions. These distortions are referred to as intrinsic. The distortions may also arise only as a result of the fixing on a substrate holder and are possibly even reversible, i.e. disappear as a rule when they substrate holder is removed. These distortions are referred to as extrinsic. Since the substrates are usually processed however on a substrate holder, great importance is also attached to compensation of distortions caused by a substrate holder. According to the invention, such distortions can also be compensated for. Extrinsic distortions are caused for example by specific substrate holder topography. No substrate holder surface can be ground and polished perfectly und they always exhibit waviness.

If such a substrate holder is used for example in a bonding installation, it may be advantageous to fix the substrates on the substrate holder and then to carry out a method according to the invention for the compensation of distortions, in order to adapt the substrate surface intended for the bonding process in such a way that the bonding result is optimum. It is even conceivable for the distortions to be compensated for before the fixing of the substrate on the substrate holder, such that the desired substrate surface is present when the substrate is fixed on the substrate holder.

The invention is suitable for compensating for all the stated types of distortion,

The local action comprises or produces:
a physical and/or chemical reaction, and/or
mechanical and/or thermal stresses, and/or
distortions and/or warping of the substrate, in particular at the edge of the substrate, and/or
material removal at the at least one substrate surface.

The distortions are located in particular on an active substrate surface. The active substrate surface in particular comprises structures, such as for example LEDs, MEMS etc.

One or more distortions can be compensated for. They can be compensated for simultaneously or successively.

The at least one local action can by produced on the active substrate surface and/or a passive substrate surface which lies opposite the active substrate surface. A plurality of local actions can be produced, which are produced simultaneously or successively.

If a plurality of local actions are produced, the latter can be produced on the active substrate surface and/or the passive substrate surface.

According to the invention, it is in particular advantageously possible to introduce permanent, in particular plastic, changes in the substrate, preferably targeted locally. According to the invention, it is thus in particular possible to deform the substrate locally and/or globally in such a way that its surface topology is adapted to an intended state.

In a preferred embodiment, provision is made such that the local action is generated by electromagnetic radiation, preferably by a laser. The electromagnetic radiation or the laser has the necessary parameters, with which a physical and/or chemical reaction can be triggered in the immediate vicinity, so that the distortion can be compensated for.

It is not necessary for the electromagnetic radiation or the laser to have to act precisely on the point of the distortion. The laser must act on the immediate vicinity of the distortion in such a way that the distortion is compensated for.

In another preferred embodiment, a laser is used, the pulse duration of which can be adjusted. If the pulse duration cannot be adjusted, use is made of a laser with as short a pulse duration as possible, preferably in the pico- or femtosecond range. Short pulse durations bring about purely local heating, which may be necessary to bring about the aforementioned physical and/or chemical reaction which is required for the compensation of the distortion.

The pulse durations are less than 10⁻⁵ s, preferably less than 10⁻⁷ s, still more preferably less than 10⁻⁹ s, most preferably less than 10⁻¹² s, with utmost preference less than 10⁻¹⁵ s.

The laser power is greater than 1 Watt, preferably greater than 10 Watt, still more preferably greater than 100 Watt, most preferably greater than 1000 Watt, with utmost preference greater than 10,000 Watt.

In another preferred embodiment, a laser is used, the laser beam shape whereof can be shaped, in particular by means of optical elements. It is thus advantageously possible to alternate between a circular and a longitudinal laser beam. A longitudinally shaped laser beam will lead to anisotropic effect, since its horizontal photon density distribution differs from its vertical photon density distribution.

In another preferred embodiment, the laser is used in a maskless exposure device, which comprises at least one SLM (spatial light module), in particular at least one DMD (digital micromirror device). By means of the scanning and the locally resolved bombardment of the substrate surface, the compensation of the distortion can be particularly well controlled.

In another preferred embodiment, monitoring of the substrate surface is carried out, wherein the compensation is observed in-situ.

A laser is preferably coupled into an optical system of a metrology device, which can be used to monitor the substrate surface. A particularly efficient capability is thus created to observe the compensation of the distortion in-situ.

The following local actions, in particular reactions or physical and/or chemical effects, are conceivable, which can lead to the compensation of the distortion.

It is conceivable for an effect, for example, of a laser beam to lead to local melting and then solidification of the local environment on which for example the laser acts. By means of the melting and solidification, internal stresses can be built up or reduced locally in the substrate.

It is also conceivable for the melting and solidification to lead to a permanent change in volume. On the assumption of the mass being retained, the material, and with the same density therefore also the volume, must continue to be retained. However, in the melting process atoms leave the melt bond and immediately sublimate on account of the immense heat of the laser beam and are given off into the surroundings. The mass thus becomes less and with constant density also the volume. The effect of the reduction in volume is that the surroundings can expand into the region of the laser, in particular if the surroundings are under residual compressive stresses.

A further possibility takes into consideration the fact that the density changes during the solidification process. A change in density can take place either due to the removal of a dissolved component, the resorption, i.e. the dissolution of a component, or by bubble or pore formation. The bubble or pore formation is usually undesired, but can be acceptable if the side of the laser action is ground away or polished away in a subsequent process step.

It is also conceivable for the effect of the electromagnetic radiation or the laser beam to lead to a solid phase transition. The solid phase transition should preferably not be reversible. In this case, the substrate has a least one metastable phase in order transition by the heat effect of the laser beam into a stable phase, which also remains stable after the cooling of the surroundings. The amorphisation of at least one substrate surface, for example, is conceivable, which then recrystallises after the effect of the laser beam.

It is also conceivable for tensile or compressive stresses to arise due to the phase transition, which deform the immediate vicinity, In particular elastically.

A further possibility takes into consideration the fact that, due to the action of the laser beam and the associated heating, thermal stresses and/or an expansion of the material are generated, which lead to a plastic deformation of the material. In this case, the material is preferably a metal. It would be conceivable, for example, for the metallic TSV surfaces in a hybrid substrate surface to be bombarded in targeted manner in order to produce a plastic deformation there, which leads to compensation of the distortions.

In another exemplary embodiment, the local action is produced by a coating which is applied on the substrate surface.

The substrate surface, in particular the passive substrate surface, is preferably coated. Internal stresses and/or thermal stresses are built into the coating.

In particular, the coating is a metal, a metal alloy, an oxide or a ceramic. Internal stresses can be established by a bombardment of the coating with particles on the atomic scale, in particular ions, less preferably by coarse-grained particles on the nanometre or micrometre scale.

The internal stresses thus established are predominantly internal compressive stresses. Thermal stresses can be established by the targeted deposition of a material with a known thermal expansion coefficient. If the thermal expansion coefficient of the substrate differs from that of the coating, either tensile or compressive internal stresses are established in the coating during cooling from a coating temperature to ambient temperature.

The coating can preferably be structured. As a result of the structuring, i.e. through the removal of material, internal stresses are reduced or increased locally in the coating. The coating thus also influences the substrate lying beneath and therefore the distortion. In particular, the structuring can take place in such a way that the coating is removed locally only partially in the thickness. As a result of the establishment of a relief, the stress states in the coating and therefore also in the substrate can be changed and the distortion in the substrate can be compensated for.

In a preferred embodiment, the coating is an oxide, in a particularly preferred embodiment a native oxide. Many substrates which come into contact with the surroundings are advantageously always coated with a native oxide, which is several nanometre thick. The expensive production of a coating is thus omitted.

The coating can include in particular at least one of the following materials or material classes:
oxide, in particular
   silicon dioxide (SiO2), preferably
      native silicon dioxide (SiO2)
ceramics, in particular
   silicon nitride (Si3N4)
semiconductors, in particular
   Ge, Si, Alpha-Sn, B, Se, Te
compound semiconductors
   GaAs, GaNInP, InxGa1-xN, InSb, InAs, GaSb, AlN, InN, GaP, BeTe, ZnO, CuInGaSe2, ZnS, ZnSe, ZnTe, CdS, CdSe, CdTe, Hg(1-x)Cd(x)Te, BeSe, HgS, AlxGa1-xAs, GaS, GaSe, GaTe, InS, InSe, InTe, CuInSe2, CuInS2, CuInGaS2, SiC, SiGe
metal, in particular
   Cu, Ag, Au, Al, Fe, Ni, Co, Pt, W, Cr, Pb, Ti, Ta, Zn, Sn
metal alloy
polymer, in particular
   sol-gel polymers, in particular
polyhedral oligomeric silesquioxane (POSS), polydimethyl siloxane (PDMS), tetraethyl orthosilicate (TEOS), poly(organo)siloxanes (silicon), perfluoropolyether (PFPE)

The stress state of the coating and therefore of the substrate lying beneath is preferably changed by the local, targeted removal or structuring of the oxide. This change in turn leads to the compensation of the distortion. If the native oxide is too thin, a thermal oxide can be produced. Particularly advantageously, the thermal oxide is already produced before the production of active components on the active substrate surface. The active components are thus not exposed to a high thermal load. In a particularly preferred procedure, a substrate with thermal oxide is bought in and the active substrate surface is freed from thermal oxide by back-thinning, so that the thermal oxide remains present only on the passive substrate surface.

In another preferred embodiment, the coating is a polymer. The internal stresses are produced here chiefly by the curing of the polymer, which leads in particular to cross-linking of the polymer. The structuring of the polymer takes place by photolithography and/or imprint lithography.

According to the invention, tensile or internal compressive stresses (referred to in the following simply as internal stresses) can in particular be produced. The internal stresses thus produced bring about a mostly elastic deformation of the surrounding material and thus are in a position to compensate for the distortions present. If the internal stresses remain unchanged, the elastic deformation and therefore the compensation of the distortions also remains unchanged. The elastic compensation of distortions describes a further possibility for compensating for distortions, in addition to the compensation of distortions by permanent, in particular plastic, deformation. The mentioned internal stresses are produced in particular by layers deposited on the at least one substrate surface, which layers can in particular be structured.

In particular, the invention is suitable in particular for compensating for deviations from the intended state which result from process steps which have already taken place, in order to prepare the substrates for subsequent process steps, in particular in order to be able to achieve better results in the subsequent process steps.

The invention can preferably also be used to compensate for, in particular to prevent, known and/or expected irregularities in future process steps in advance. In a preferred embodiment, expected distortions are prevented. In an alternative, particularly preferred embodiment, the substrates are deformed by means of the method according to the invention, in such a way that the process can take place more uniformly and thus minimise, in particular largely eliminate, irregular distortions.

According to another preferred embodiment, provision is made such that the at least one local action produces deformations of the substrate, in particular at the edges of the substrate. In particular, the substrate is bent upwards at least in sections at the edges. This can be brought about in particular by bombardment with a laser at the edges of the substrate. The distortions are compensated for by the deformations in the substrate.

In particular, the intended state of the substrate can appear such that the periphery of the substrate is curved slightly upwards. The actions according to the invention are carried out in such a way that on the one hand the distortions on the substrate surface can be compensated for, and that at the same time the periphery of the substrate is arched slightly upwards. In a subsequent bonding process, the emergence of edge defects (engl.: edge voids) can thus preferably be reduced or even prevented.

In a particularly preferred embodiment, the arching of the substrate is adjusted such that the edges arch in a concave manner with respect to the bond contact surface, to the extent that the natural acceleration of the bonding wave to the wafer edge is counteracted, and the bonding wave runs at a continuous speed in particular up to 5 mm, preferably up to 3 mm, particularly preferably up to 2 mm to the edge, and/or has a radius of curvature at the contact point of the wafer which deviates by a maximum of +/−30% or preferably +/−20% from the radius of curvature at the contact point of the wafer which is present after 50 mm from the bond initiation point.

In an alternative embodiment, the edges of at least one of the two wafers are arched in a convex manner with respect to the bond contact surface, to the extent that in the subsequent bonding process the smaller distortion of the wafer often to be observed in the edge region, in particular caused by the falling atmospheric pressure in the space between the wafers, is prevented by compensation by means of the method according to the invention immediately before the contact point of the wafers along the bonding wave.

In another exemplary embodiment, the local action is produced by removal of material of the substrate.

In particular, parts of the substrate are removed at at least one of the substrate surfaces. The removal takes by sawing, laser, ions or atom bombardment or any other suitable kind of material removal. As a result of the removal of material, the substrate, in particular when it has internal stresses, is correspondingly deformed in the surrounding area of the material removal. This embodiment is suitable chiefly for use on the passive substrate surface, especially if the latter is to be thinned back by a back-thinning process in a subsequent process step.

Especially after the distortions have been compensated for according to the invention in such a way that the desired intended state has resulted on the substrate, in particular on the at least one substrate surface, the substrate can be further processed.

If the substrate has a substrate surface which has been treated lithographically, the invention can be used to change a distortion of the lithographic structure. It is thus ensured that following process steps are carried on an undistorted or rectified layer.

In a particularly preferred embodiment, a method is carried out, wherein a measurement of the substrate surface takes place and thereafter the compensation of the distortions takes place on the substrate surface and the substrate surface is subsequently remeasured.

In particular, a measurement of at least one, in particular the active, substrate surface is carried out in a first process step. The measurement preferably takes place in an interferometer. The measurement of the substrate surface leads to a distortion chart. The distortion chart represents the deviation of the actual state from the intended state. The distortion chart is stored by software or hardware.

In a second optional process step, a calculation of the necessary compensations in order to transform the current state into the intended state takes place, i.e. to compensate accordingly for all the distortions. This step can be dispensed with if the compensation method according to the invention can be carried out by obvious steps. If, for example, distortions have to be compensated for along an x-axis and it is known that the use of the compensation method according to the invention delivers the necessary result at a point of the x-axis, an exact calculation can be dispensed with.

The calculations are preferably carried out with the aid of models for more complex compensation requirements, said models describing the effect of the compensation method on the distortion. In particular, they are mechanical models. Alternatively, models can preferably also be used which describe experimentally acquired data. The two variants can be or are preferably combined and the mechanical model is preferably continuously calibrated in particular with experimentally acquired data. Particularly preferably, the models use at least in part finite element method (FEM) simulations.

In a third process step, at least one compensation method according to the invention is carried out to compensate for the distortions. In a particularly preferred procedure, the use of the compensation method according to the invention takes place in parallel with the measurement of the substrate surface. By means of a control loop, each compensation of a distortion that has been carried out can be monitored and accordingly regulated. By means of the in-situ monitoring of the compensation, particularly quick, exact and cost-effective compensation of all the distortions is possible.

In a fourth process step, the at least one, in particularly the active, substrate surface is again measured. The measurement of the substrate surface again leads to a distortion chart. The distortion chart represents the divergence of the actual state from the intended state. The distortion chart is stored by software or hardware. If the distortion chart continues to show too many and/or excessively severe distortions, several positions of the substrate surface can again be approached and the third process step is accordingly repeated. If a distortion chart is measured with minimal distortions, in particular no longer any distortions, the method can be discontinued.

In a particularly preferred embodiment, the distortion impressed by the compensation method according to the invention is determined by taking the difference in the measurement before the method and after the method. This information can be used in a feedback loop for the in particular continuous calibration of the compensation method according to the invention. The process and/or device parameters for the subsequent processed substrates can thus preferably be selected such that the results better achieve the sought intended state. This continuous calibration preferably enables stable results over a large number of substrates, if the quality of these substrates is subject to a trend.

Another subject-matter of the invention relates to a method for bonding two substrates, wherein distortions of at least one of the substrates are compensated for by the method according to the invention or the device according to the invention and thereafter the two substrates are bonded together.

The course of the bonding wave in particular can be influenced by the compensation of the distortions according to the invention. The bonding wave should preferably propagate symmetrically and/or concentrically with respect to the contact point.

Particularly preferably, the distortions are influenced in such a way that the speed of the bonding wave diminishes towards the edge. The formation of edge defects is thus minimised as far as possible or even prevented. At least one of the two substrates participating in the bonding process is curved convexly towards the bond interface. The distortions are thus compensated for in particular in such a way that a slight convex curvature towards the bond interface results.

In at least one of the two substrates, the distortions are preferably compensated for in such a way that the substrate surface can be described during the bonding as part of a sphere, a parabola or an ellipsoid. By means of such a mathematical formation of the substrate surface, ideal bonding results can be achieved, i.e. the deviations between the partial regions of the two substrates to be bonded together are minimised.

The first substrate can be bonded with a second substrate. It is conceivable that the distortions of the second substrate have also been compensated for by the method according to the invention. It is however also conceivable that the distortions of the first substrate have been compensated for in such a way that the regions of the two substrates to be bonded together are congruent, or have minimal deviations from one another. In this case, the compensation of the distortions only has to be carried out on the first substrate. A prerequisite for a good bonding result is in particular that the positions of the regions on the two substrates to be bonded together are very well measured.

The invention is particularly suitable for compensating for the distortions of substrate surfaces of two hybrid substrates, which comprise electrical and dielectric regions. The metallic regions of the hybrid substrates are the surfaces of the TSVs (engl. through silicon vias), the correct positioning whereof must be guaranteed before and after the bonding process, in order to guarantee an intact electrical connection between the two substrates. In particular, distortion charts as described in publication WO 2012079786A1 are adopted.

### BRIEF DESCRIPTION OF THE DRAWINGS

Further advantages, features and details of the invention emerge from the following description of preferred examples of embodiment and with the aid of the drawings. The latter show diagrammatically:

FIG. 1a is a plan view of a substrate in an intended state,

FIG. 1b is a plan view of a substrate in an actual state,

FIG. 1c is a plan view of a substrate with a compensated distortion,

FIG. 2 is a side view with a plurality of compensation methods according to the invention,

FIG. 3 is a side view of a substrate with global distortions, and

FIG. 4 is a side view of the substrate without global distortions.

### DETAILED DESCRIPTION OF THE INVENTION

Identical components or components with the same function are denoted by the same reference numbers in the figures.

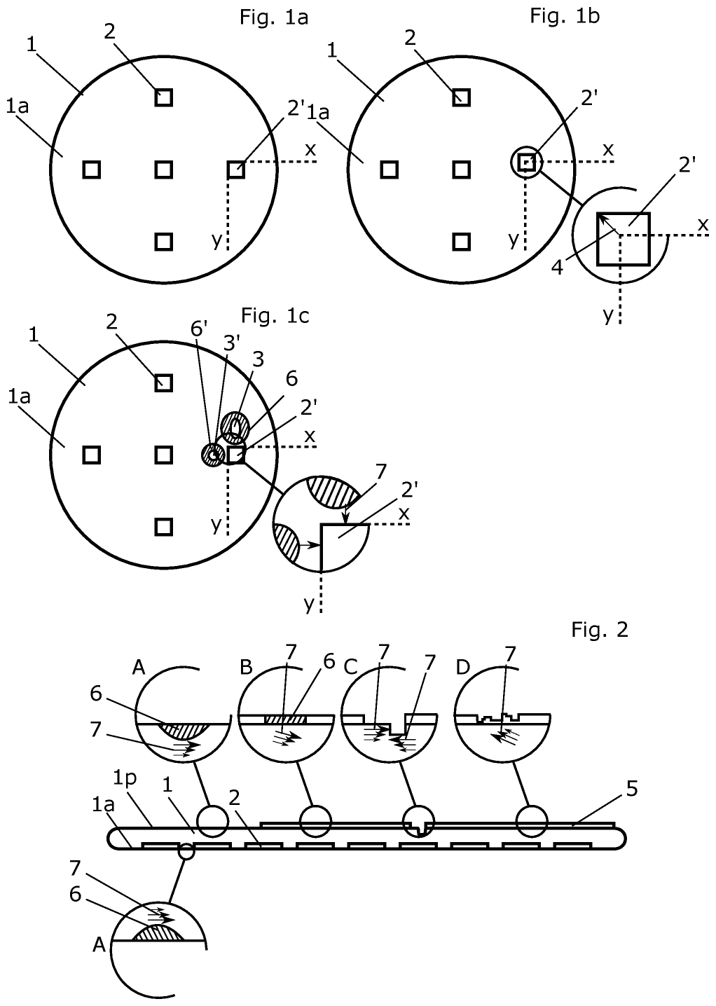

FIG. 1a shows a plan view of a very simplified substrate 1 in an intended state. Substrate 1 comprises five structures 2 on its active substrate surface 1a. Structures 2 can be components such as MEMS, LEDs or chips. It is also conceivable for structures 2 to be lithographically produced structures. For the sake of simplicity, only five structures 2 are represented and each of structures 2 is symbolised by a simple square. The number, shape, orientation of structures 2 can generally be arbitrary. FIG. 1a represents the intended state, i.e. the optimum arrangement and orientation of structures 2 with respect to substrate 1. FIG. 1a represents a coordinate system with an X- and a Y-axis for right-hand structure 2. These two axes span a plane for right-hand structure 2.

FIG. 1b shows a plan view of a very simplified substrate 1 in an actual state and in the right-hand lower corner an enlargement of a structure 2′. As a result of errors in the production or influencing of active substrate surface 1a and/or a passive substrate surface 1p, several, generally all, structures 2, 2′ can be subject to a deviation 4 from their intended positions and orientations. This deviation 4 is represented in FIG. 1b with the aid of right-hand structure 2′. Structure 2′ is shifted along the x- and y-axis. A slight rotation with respect to the ideal position would also be conceivable. For the sake of clarity, this is disregarded in the figure. Deviation 4 from the intended position is referred to as a distortion.

FIG. 1c shows a plan view of a very simplified substrate 1, in which a compensation method according to the invention, in the present case the action of a laser 3, 3′, leads to a compensation 7 of distortion 4. Two laser points 3, 3′ are represented. Laser point 3 has an elongated shape and is orientated vertically, laser point 3′ has a circular shape. Laser points 3, 3′ each produce corresponding areas of influence 6, 6′, in which physical and/or chemical reactions take place, which lead to compensation 7 of distortion 4. These two laser points 3, 3′ are also intended to illustrate that a plurality of laser point shapes are possible.

In FIGS. 1a-1c, the compensation method according to the invention is carried out on active substrate surface 1a. All compensation methods can also be carried out on passive substrate surface 1p, which lies opposite active substrate surface 1a.

FIG. 2 shows a side view of a substrate 1. Substrate 1 comprises on its active substrate surface 1a a plurality of structures 2. In the present case, they could for example be microchips which have been produced in substrate 1. Generally, the substrate will again exhibit distortions at different positions. These distortions are not explicitly represented in FIG. 2. Several exemplary compensation methods according to the invention are represented with the aid of enlargements (A-D).

The two enlargements A each describe compensation 7 of distortions 4 by the introduction of energy with the aid of electromagnetic waves, in particular a laser and/or particles, in particular ions. An area of influence 6 arises in each case in substrate 1, in which a physical and/or chemical reaction takes place, which in particular is irreversible and so in each case can contribute to compensation 7 of distortion 4. Enlargements A have been represented on active substrate surface 1a and on passive substrate surface 1p, in order to show that this type of compensation 7 can be carried out advantageously on both substrate surfaces 1a, 1p.

Enlargement B describes compensation 7 of distortions 4 by the introduction of energy by means of electromagnetic waves, in particular a laser and/or particles, in particular ions, into a coating 5, which is present on substrate 1. Coating 5 is preferably located on passive substrate surface 1p, since active substrate surface 1a is preferably further processed uncoated.

Coating 5 is changed in area of influence 6, in such a way that tensile or compressive stresses are built up in it. The latter can be generated in turn by the same physical and/or chemical reaction as in other compensation methods. It would for example be conceivable for a transition of a metastable phase into a stable phase to take place, which has a larger volume than the metastable phase. In this case, compressive stresses are built up. If the stable phase has a smaller volume than the initial phase, tensile stresses build up. The implantation of ions, atoms or molecules is conceivable, which lead to the build-up of compression properties. The removal of material by sublimation and/or melting is conceivable. The removal of individual chemical components of a compound by the supply of heat is conceivable. Coating 5 could for example outgas by a supply of heat and in particular lose water, oxygen or nitrogen compounds. The coating is preferably an oxide, most preferably a native oxide.

Enlargement C describes compensation 7 of distortions 4 by the complete removal of coating 5 and/or even the removal of parts of substrate 1. The partial removal of substrate 1 can also be carried out on active substrate surface 1a, but it is less advantageous there, since structures 2 could this be damaged and/or contaminated. Furthermore, a partial removal of substrate 1 on passive substrate surface 1p can be removed in subsequent process steps by a back-thinning process.

Enlargement D describes compensation 7 of distortions 4 by structuring of coating 5. For this purpose, coating 5 is structured by a lithographic process. The structuring preferably takes place with the aid of imprint lithography. In this case, the material of the coating is preferably a polymer. The use of maskless photolithography is also conceivable. In maskless photolithography, a device with at least one SLM, in particular a DMD, is used. As a result of the structuring, the effect of internal stresses of coating 5 on the substrate lying beneath is changed and thus permits compensation 7 of distortions 4.

Of all the aforementioned compensation methods, the direct influencing of substrate 1 by means of a laser is the most efficient type, since the deposition of a coating 5 can be completely dispensed with. The use of a coating 5 has advantages when coating 5 arises due to natural causes, in particular the atmosphere, as is the case with native oxides.

The embodiments described above serve merely to illustrate the idea behind the invention and do not limit the subject-matter of the invention in any way.

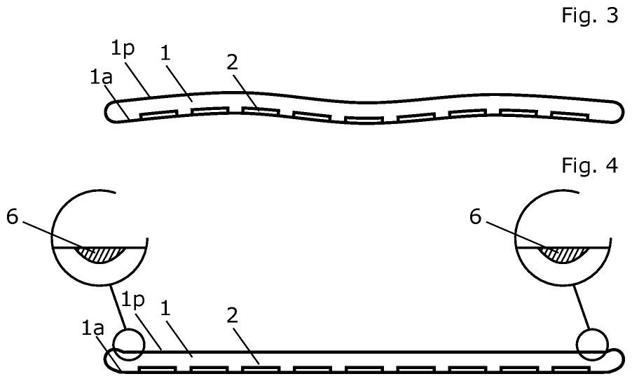

FIG. 3 shows a side view of a substrate 1 with global distortions. The global distortions are location-dependent distortions over entire substrate 1. By means of a location-dependent, targeted use of the method according to the invention, in particular a laser, actions can be produced in areas of influence 6 (FIG. 4), which lead to the desired compensations. The compensations then lead to the desired result, for example undistorted substrate 1 (see FIG. 4).

FIG. 4 shows the use of the method according to the invention, whereby actions are produced in a targeted manner in areas of influence 6, in order to produce deformations at the edges, so that substrate 1 arches upwards at the edges. The arching is represented in an exaggerated form in the figure for the sake of clarity.

### LIST OF REFERENCE NUMBERS

1 substrate
1a active substrate surface
1p passive substrate surface
2, 2′ structure
3, 3′ laser
4 distortion
5 coating
6, 6′ area of influence
7 compensation
A, B, C, D enlargements
x, y axes

1. A method for the compensation of distortions on at least one substrate surface of a substrate, wherein at least one local action is generated on at least one of the substrate surfaces.

2. The method according to claim 1, wherein the local action is generated by electromagnetic radiation.

3. The method according to claim 1, wherein monitoring of the at least one of the substrate surfaces is carried out, and
wherein the compensation is observed in-situ.

4. The method according to claim 1, wherein the local action is produced by coating, which is applied on the at least one of the substrate surfaces.

5. The method according to claim 1, wherein the local action is produced by removal of material of the substrate.

6. The method according to claim 1, wherein the at least one local action brings about deformations of the substrate.

7. The method according to claim 1, wherein a measurement of the at least one of the substrate surfaces takes place and then the compensation of the distortions on the at least one of the substrate surfaces takes place and subsequently the at least one of the substrate surfaces is measured again.

8. A method for bonding two substrates, comprising;
compensating for distortions of at least one substrate surface of the substrates; and
then bonding the two substrates together,
wherein at least one local action is generated on at least one of the substrate surfaces.

9. A device for the compensation of distortions on at least one substrate surface of a substrate, wherein at least one local action can be produced on at least one of the substrate surfaces.

10. The device according to claim 9, comprising means for generating the local action, wherein the means for generating the local action comprise a laser.

11. (canceled)

12. The method according to claim 2, wherein the electromagnetic radiation is generated by a laser.

13. The method according to claim 6, wherein the deformations of the substrate are brought about at edges of the substrate.
